(19) United States
(12) Patent Application Publication
(10) Pub. No.: US 2006/0189027 A1
(43) Pub. Date: Aug. 24, 2006

(54) Method of fabricating avalanche photodiode

(75) Inventor: Do-Young Rhee, Yongin-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/215,905

(22) Filed: Aug. 31, 2005

(30) Foreign Application Priority Data
Feb. 23, 2005 (KR) 2005-15166

(51) Int. Cl. H01L 21/00

(52) U.S. Cl. 438/91; 438/380; 438/94

(57) ABSTRACT

A method of fabricating an avalanche photodiode is disclosed. The method includes the steps of growing a plurality of semiconductor layers sequentially on a semiconductor substrate; growing diffusion layer patterns having diffusion coefficients different from that of an amplifying layer on a portion on which a peripheral portion of a diffusion area is to be formed, on the semiconductor layers; and forming the diffusion area such that the depth of the peripheral portion thereof is different from that of the central portion thereof by diffusing impurities through the diffusion patterns.

### CLAIM of PRIORITY

This application claims the benefit of the earlier filing date, pursuant to 35 USC 119(a) to that patent application entitled “METHOD OF FABRICATING AVALANCHE PHOTODIODE” filed in the Korean Industrial Property Office on Feb. 23, 2005 and assigned Serial No. 2005-15166, the contents of which are hereby incorporated by reference.

### BACKGROUND OF THE INVENTION

1. Field of the Invention

The present invention relates to fabrication of an optical device, and more particularly to a method for fabricating an avalanche photodiode including a diffusion area.

2. Description of the Related Art

A photodiode is a type of photoelectric conversion device, that converts a received light to electric signals and subsequently outputs the converted electrical signals. Among photodiodes, an avalanche photodiode is a type of photoelectric conversion device which can convert and amplify the converted electric signals and subsequently output the amplified signals.

The avalanche photodiode must be formed accurately so that an included amplifying layer has an intended structure to realize the amplifying characteristics of the converted optical signals, and should overcome a yield phenomenon generated at the edges of a Zn diffusion area.

FIG. 1 is a cross-sectional view of a conventional avalanche photodiode. Referring to FIG. 1, the conventional avalanche photodiode 100 includes an absorption layer 120, a grading layer 130, an electric field buffer layer 140, and an amplifying layer 190, which are sequentially grown on the semiconductor substrate 110. Upper electrodes 181 and 182 are formed on the upper portion of the amplifying layer 190, and a lower electrode 162 is grown on the lower portion of the semiconductor substrate 110. A surface protection layer 161 is grown over the upper layers to protect the internal layers The semiconductor substrate 110 can be formed of a semiconductor material of N⁺—InP, (N⁺-doped Indium Phosphate) and the absorption layer 120 can be formed of N—InGaA (N-doped Indium Gallum Arsenic). In addition, the grading layer 130 can be formed of N—InGaAsP (N-doped Indium Gallum Arsenic Phosphate), and the electric field buffer layer 140 and the amplifying layer 190 can be formed of N—InP. The surface protection layer 162 can be formed of a material selected from the group consisting of SiNx, e.g., Silicon Nitride, Silicon Nitrate.

A diffusion area 150 and guard ring areas 171 and 172 are formed at predetermined portions of the upper end of the amplifying layer 190. The diffusion area 150 includes a center portion 152 and peripheral portions 151 and 153. The height Wm and A of the central portion 152 from the electric field buffer layer 140 is lower than the heights B of the peripheral portions 151 and 153 from the electric field buffer layer 140. That is, central area 152 is formed deeper into amplifying layer 190 than regions 151, 153.

The diffusion area 150 is conventionally formed by diffusion of impurities and a drive-in process, after a portion of the amplifying layer 190 is recess-etched.

The light inputted into the avalanche photodiode 100 excites the absorption layer 120, which generates an electron and a hole. The electron and the hole, are referred to as an electron-hole pair (hereinafter, EHP). Since inverse voltage is applied to the avalanche photodiode 100, in the generated EHP the electron is discharged through an N type lower electrode 162 and the hole passes through the grading layer 130 and the buffer layer 140, sequentially, and is inputted to the amplifying 190. After the hole is amplified by amplifying layer 190, it is outputted through the upper electrode 181, which is of P type material.

Since the photodiode 100 amplifies the electric signals converted from the light internally, it can output electric signals of relatively low noise and large output as compared with an amplifying device of another type.

The avalanche photodiode needs an additional operation time to amplify the electric signals therein, and the operation time of the avalanche photodiode increases in proportion to the thickness of the amplifying layer. However, the increase in the operation time deteriorates the bandwidth characteristics of the avalanche photodiode. For reference, the amplifying layer of the avalanche photodiode up to a maximum thickness of 0.5 μm is able to obtain the operation characteristics of 2.5 Gbps. While, an amplifying layer of a maximum thickness of 0.2 μm is able to obtain operation characteristics of 10 Gbps.

However, creation of the diffusion area requires great care as there is a possibility of an edge yield phenomenon if the width of the amplifying layer is too small. The edge yield phenomenon can be overcome by using the diffusion area and the guard rings (171, 172) to prevent the electric field from being concentrated on the edge.

In addition, as a portion of the amplifying layer may be etched by wet or dry etching processes, the etched diffusion area has a problem of having a large allowable error in the range of more than ±100 Å.

Therefore, the conventional method of creating the diffusion area has a problem in that the manufacturing processes are complicated in order to minimize the allowable error range and the yield rate of the product lowers.

### SUMMARY OF THE INVENTION

Accordingly, the present invention has been made to solve the above-mentioned problems occurring in the prior art and provides additional advantages, by providing a method of fabricating an avalanche photodiode by which a diffusion area can be easily formed and generation of errors can be minimized when forming the diffusion area.

In one embodiment, a method of fabricating an avalanche photodiode includes the process of growing a plurality of semiconductor layers sequentially on a semiconductor substrate; growing diffusion layer patterns having diffusion coefficients different from that of an amplifying layer on a portion on which a peripheral portion of a diffusion area is to be formed and forming the diffusion area such that the depth of a peripheral portion thereof is different from that of a central portion by diffusing impurities through diffusion patterns.

### BRIEF DESCRIPTION OF THE DRAWINGS

The above features and advantages of the present invention will be more apparent from the following detailed description taken in conjunction with the accompanying drawings, in which:

FIG. 1 is a cross-sectional view for showing a conventional avalanche photodiode; and

FIGS. 2A to 2F are views for showing the steps of manufacturing an avalanche photodiode according to the present invention.

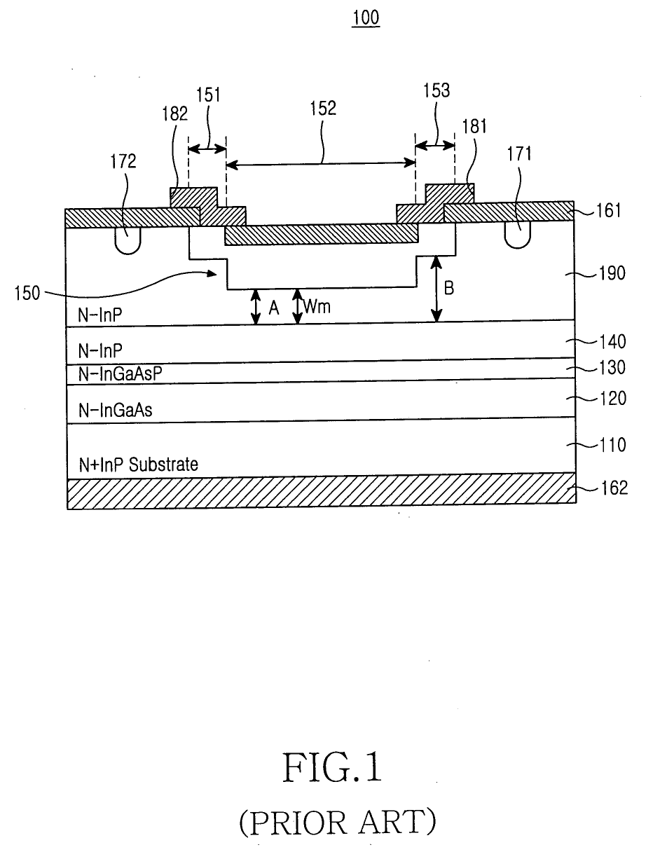

### DETAILED DESCRIPTION

Hereinafter, embodiments of the present invention will be described with reference to the accompanying drawings. For the purposes of clarity and simplicity, a detailed description of known functions and configurations incorporated herein will be omitted as it may make the subject matter of the present invention unclear.

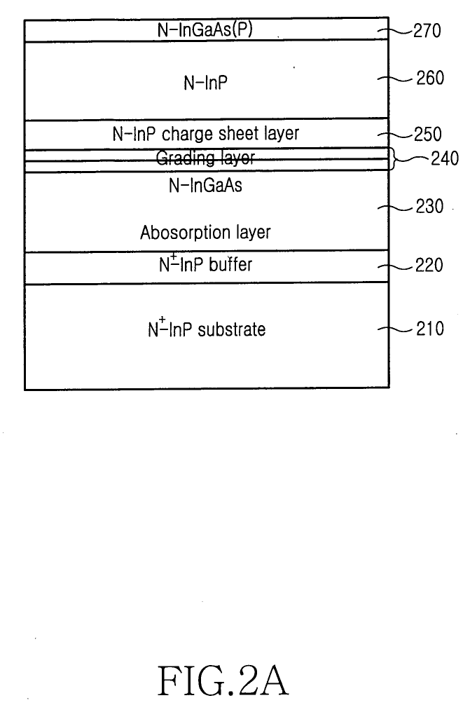

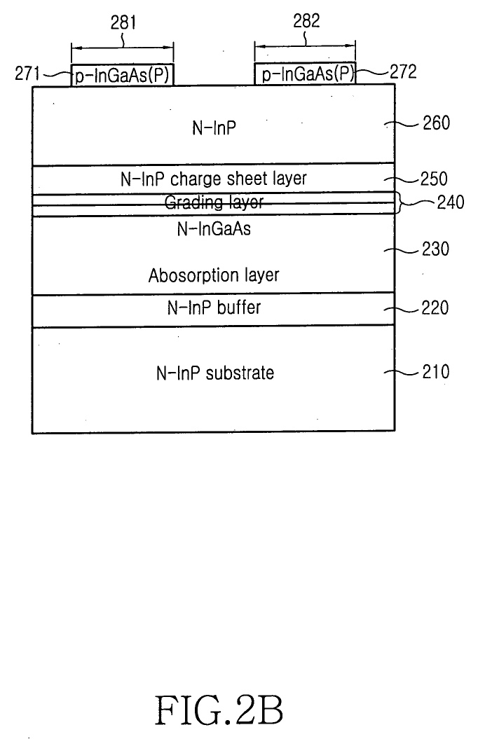

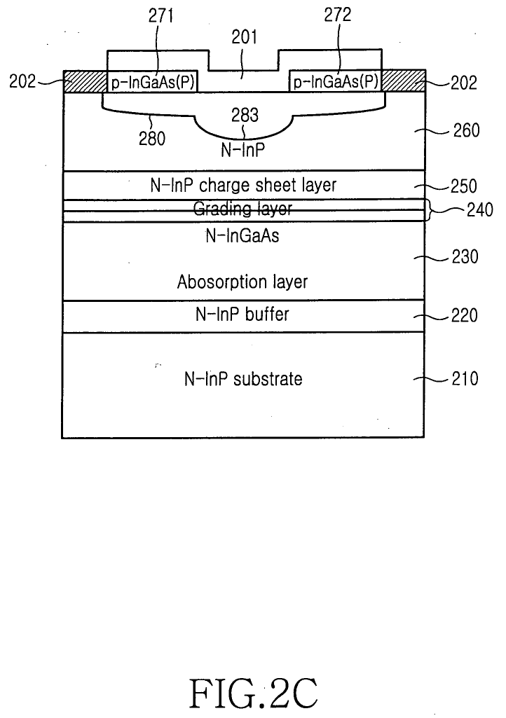

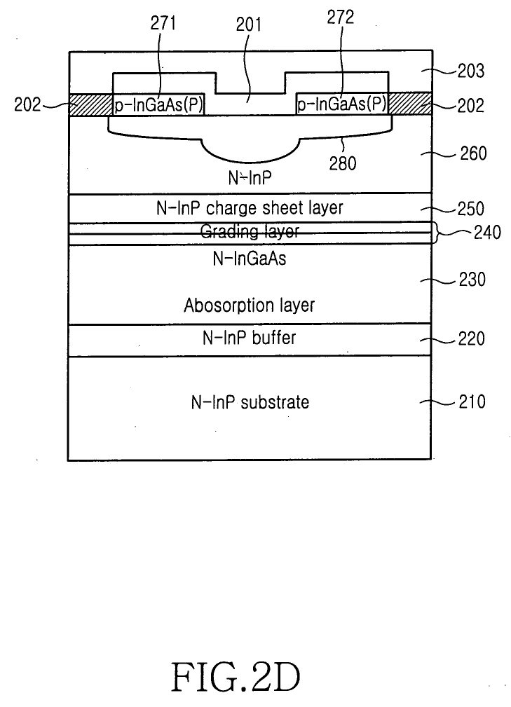

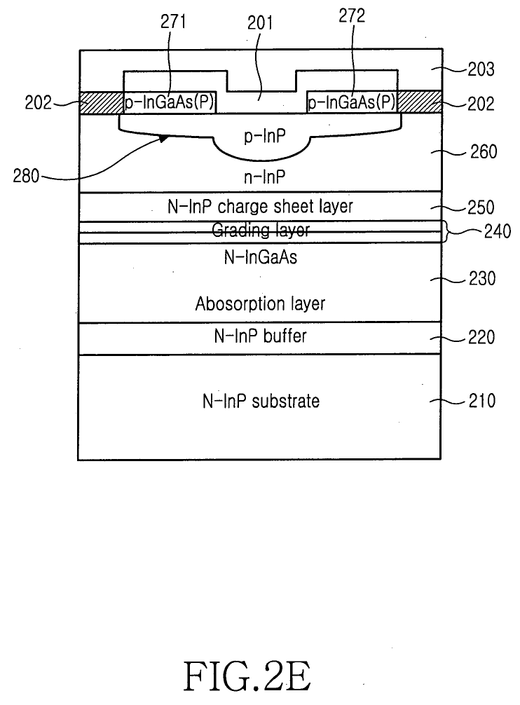

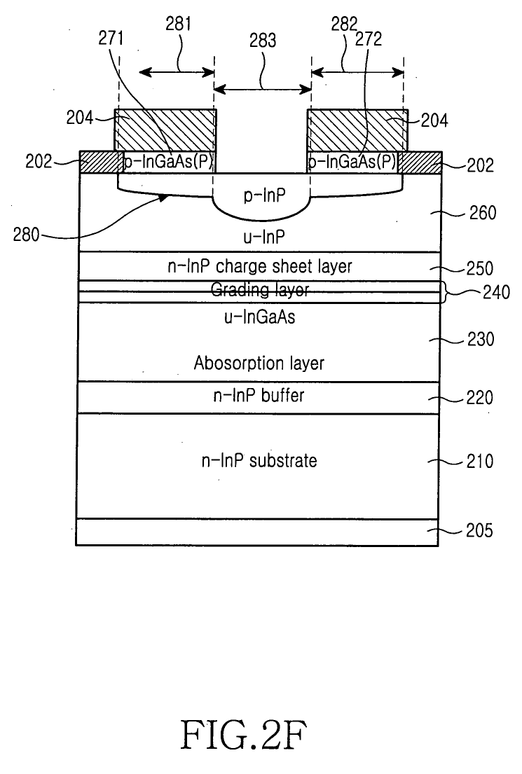

FIGS. 2A to 2F are views showing steps of manufacturing an avalanche photodiode according to the present invention.

FIG. 2A shows a state in which semiconductor layers are sequentially grown on a semiconductor substrate. Referring to FIG. 2A, the avalanche photodiode includes a buffer layer 220, an absorption layer 230, a grading layer 240, an electric field buffing layer 250, and an amplifying layer 260, which are sequentially grown on the semiconductor substrates.

The semiconductor substrate 210 can be formed of N⁺—InP, and the buffer layer 220 is grown on the semiconductor substrate 210. The buffer layer 220 also can be formed of N⁺—InP or other similar N⁺-doped semiconductor material.

The absorption layer 230 is grown on buffer layer 220, and the absorption layer 230 can be formed of N—InGaAs or other similar N-doped semiconductor material. The absorption layer 230, as discussed previously, is excited by an absorbed light and forms an electron-hole pair.

The grading layer 240 includes a plurality of layers having a band gap between InP and InGaAs, wherein a hole, among the electron-hole pair generated in the absorption layer 230, is injected into the amplifying layer 260. The grading layer 240 can be formed of N⁻—InGaAsP.

The electric field buffing layer 250 has a density and a thickness which are well regulated, and is called a charge sheet layer. The electric field buffing layer 250 can be formed of N—InP.

The amplifying layer 260 is grown on the charge absorbing layer 250, and can be formed of N—InP, for example. FIG. 2B is a view for showing a state in which diffusion patterns 271 and 272 are formed at corresponding positions for forming peripheral portions 281 and 282 on amplifying layer 260. FIGS. 2C to 2E are views for showing processes in which impurities of Zn or Cd or other materials having similar properties, are doped in the amplifying layer 260 on which the diffusion patterns 271 and 272 are formed.

After the diffusion area 280 is formed, the diffusion patterns 271 and 272 are formed on the amplifying layer 260. The diffusion patterns 271 and 272 are made of a material having a diffusion coefficient different from that of the amplifying layer 260. More specifically, impurities of Zn or Cd, or other materials having similar properties, are diffused and driven-in on a portion of the amplifying layer 260 to form an impurity profile as shown in FIG. 2F.

That is, as shown in FIG. 2C, an impurity layer 201 for doping the amplifying layer 260 is formed on the amplifying layer 260 on which the diffusion patterns 271 and 272 are formed, and current blocking layers 202 are formed at a position adjacent to the diffusion patterns 271 and 272. A diffusion area 280 in which impurities of Zn or Cd, etc., is doped by diffusion and a drive-in process is formed in the amplifying layer 260.

Thereafter, as shown in FIGS. 2D and 2E, a capping layer 203, for preventing the impurity layer 201 from being diffused into the air during the doping process, is deposited. As mentioned above, the diffusion area 280, doped by the diffusion of the impurity layer 201 and the drive-in process, is formed in the amplifying layer 260.

Since the present invention uses the diffusion patterns 271 and 272, having a diffusion coefficient different from that of the amplifying layer 260, the amplifying layer 260 need not be etched to form the diffusion area. That is, the diffusion patterns enables the thicknesses of the center portion 283 and the peripheral portions 281 and 282 of the diffusion area 280 to be regulated without any recess-etching process.

The capping layer is deposited on the current blocking layer to prevent the impurities not doped in the diffusion area from being scattered into the air during the doping process. Therefore, the capping layer is removed after the doping process as shown in FIG. 2F.

Referring to FIG. 2F, the avalanche photodiode further includes upper electrodes 204, formed on the amplifying layer 260, a lower electrode 205, formed on the lower portion of the semiconductor substrate 210, and current blocking layers 202.

As the diffusion area 280 according to the present invention can be formed by a diffusion process without etching the amplifying layer differently from the prior art, the depth thereof is easily controlled and the allowable error is significantly improved.

In addition, the sizes and depths of the center portion 283 and the peripheral portions 281 and 282 of diffusion area 280 can be regulated according to the sizes, depths, and positions of the diffusion patterns 271 and 272 for forming the diffusion area 280.

The diffusion patterns 271 and 272 are formed at positions for forming the peripheral portions 281 and 282 of the diffusion area 280 on the amplifying layer 260, and can be formed of one of or a combination of InGaAs, InGsAsP, for example, which have diffusion coefficients different from that of the amplifying layer with respect to Zn or Cd.

The current blocking layers 202 can be formed of a material selected from a group consisting of dielectric materials of SiNx. Since the upper electrodes 204 are formed as a P-type ohmic electrode on the diffusion patterns of InGaAs or InGaAsP, they can have a contact resistance lower than those of the conventional electrodes by five to ten times and form a stable ohmic contact.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A method of fabricating an avalanche photodiode, the method comprising the processes of:
growing a plurality of semiconductor layers sequentially on a semiconductor substrate, wherein one layer is an amplifying layer;
growing diffusion layer patterns having diffusion coefficients different from that of the amplifying layer on a portion on which a peripheral portion of a diffusion area is to be formed, on the semiconductor layers; and
forming the diffusion area such that the depth of the peripheral portion thereof is different from that of the central portion thereof by diffusing impurities through the diffusion layer patterns.

2. A method according to claim 1, wherein the process of growing the semiconductor layers comprises the steps of:
growing a first buffer layer on the semiconductor substrate;
growing an absorption layer on the first buffer layer;
growing a grading layer on the absorption layer;
growing a second electric field buffer on the grading layer; and
growing the amplifying layer on the second electric field buffer.

3. A method according to claim 1, wherein Zn or Cd is used as the impurities.

4. A method according to claim 1, wherein the diffusion patterns are formed of materials selected from the group consisting of: InGaAs or InGaAsP.

5. A method according to claim 1, further comprising the processes of:
forming current blocking layers on portions of the semiconductor layers, on which the diffusion patterns are not grown; and
forming upper electrodes on the diffusion patterns.

6. A method of fabricating an avalanche photodiode, the method comprising the processes of:
growing a plurality of semiconductor layers sequentially on a semiconductor substrate, wherein one layer is an amplifying layer;
forming diffusion layer patterns having diffusion coefficients different from that of the amplifying layer on a portion on which a peripheral portion of a diffusion area is to be formed;
forming current blocking layers at both ends of the amplifying layer;
depositing an impurity layer on a portion of the diffusion patterns and on which the diffusion area on the amplifying layer is to be formed;
depositing a capping layer on the upper surfaces of the current blocking layers and the impurity layer;
forming a diffusion area in which the depth of the peripheral portion thereof is different from that of the center portion by diffusing impurities through the diffusion patterns; and
removing the capping layer and forming upper electrodes on the diffusion patterns.

7. A method of fabricating an avalanche photodiode, the method comprising the processes of:
growing a first buffer layer on the semiconductor substrate;
growing an absorption layer on the first buffer layer;
growing a grading layer on the absorption layer;
growing a second electric field buffer on the grading layer; and
growing the amplifying layer on the second electric field buffer;
growing diffusion layer patterns having diffusion coefficients different from that of the amplifying layer on a portion on which a peripheral portion of a diffusion area is to be formed, on the semiconductor layers; and
forming the diffusion area such that the depth of the peripheral portion thereof is different from that of the central portion thereof by diffusing impurities through the diffusion layer patterns.

8. A method according to claim 7, wherein the process of growing the semiconductor layers comprises the steps of:
